(19) United States
(12) Patent Application Publication
(10) Pub. No.: US 2021/0005688 A1
(43) Pub. Date: Jan. 7, 2021

(54) DISPLAY DEVICE AND MANUFACTURING METHOD THEREOF

(71) Applicant: Sony Semiconductor Solutions Corporation, Kanagawa (JP)

(72) Inventors: Kimihiro Shinya, Kanagawa (JP); Atsushi Yamamoto, Kanagawa (JP); Kensaku Maeda, Kanagawa (JP)

(21) Appl. No.: 16/968,824

(22) PCT Filed: Jan. 24, 2019
(86) PCT No.: PCT/JP2019/002315

§ 371 Date: Aug. 10, 2020

(30) Foreign Application Priority Data
Feb. 16, 2018 (JP) 2018-025634

(51) Int. Cl. H01L 27/32; H01L 51/52; H01L 51/56

(52) U.S. Cl. CPC H01L 27/3246; H01L 51/5275; H01L 51/5268; G02B 5/223; H01L 27/3272; H01L 51/56; H01L 27/3213

(57) ABSTRACT

In a display device including a light emitting element, light extraction efficiency and a luminance viewing angle characteristic are improved.

The display device includes a light emitting element, a condenser lens, and a scattering lens. The light emitting element is an element that emits light. The condenser lens is a lens that condenses the light emitted from the light emitting element. The scattering lens is a lens that scatters the light condensed by the condenser lens. Combination of the condenser lens and the scattering lens improves the light extraction efficiency and the luminance viewing angle characteristic.

### TECHNICAL FIELD

The present technology relates to a display device. Specifically, the present technology relates to a display device including a light emitting element and a manufacturing method thereof.

### BACKGROUND ART

In a light emitting module for displaying an image, light from a self-light emitting element such as an organic electroluminescence (EL) element is condensed by a condenser lens and is displayed. For example, there is proposed a display device including a condenser lens that condenses light emitted from a light emitting element, a reflective layer that covers the condenser lens, and a light absorption layer that covers the reflective layer (see, for example, Patent Document 1).

### CITATION LIST

### Patent Document

Patent Document 1: Japanese Patent Application Laid-Open No. 2011-100715

### SUMMARY OF THE INVENTION

### Problems to be Solved by the Invention

In the above related art, reflection of external light is suppressed while light extraction efficiency is being maintained. However, extracted light has a high directivity to the front, and thus there is a problem that a luminance viewing angle characteristic is deteriorated. Further, there is also a problem that, regarding light from a front surface of the lens, reflection of external light cannot be suppressed.

The present technology has been made in view of such circumstances, and an object thereof is to improve light extraction efficiency and a luminance viewing angle characteristic.

### Solutions to Problems

The present technology has been made in order to solve the above problems, and a first aspect thereof is a display device including: a light emitting element; a condenser lens that condenses light emitted from the light, emitting element; and a scattering lens that scatters the light condensed by the condenser lens. With this configuration, light is condensed by the condenser lens, and the condensed light is scattered by the scattering lens, thereby improving the light extraction efficiency and the luminance viewing angle characteristic.

Further, in the first aspect, a plurality of pixels may be arranged on a plane, and at least one of the plurality of pixels may include a set of the light. emitting element, the condenser lens, and the scattering lens. This makes it possible to improve the light extraction efficiency and the luminance viewing angle characteristic in at least one of the plurality of pixels.

Further, the first aspect may further include a partition wall around the pixel. This makes it possible to prevent color from mixing with colors of other pixels. In this case, the partition wall may reflect light in the pixel or may absorb light in the pixel.

Further, in the first aspect, the set of the light emitting element, the condenser lens, and the scattering lens may be provided only in a pixel of a specific color. In this case, the pixel of the specific color may be a white pixel. This makes it possible to reduce reflection of external light as necessary.

Further, the first aspect may further include a light absorption layer that absorbs light around the condenser lens or the scattering lens. In this case, the light absorption layer may cover part of the condenser lens or the scattering lens. Further, in this case, the first aspect may further include a light reflection layer that reflects light and is provided under the light absorption layer. This makes it possible to further improve the light extraction efficiency.

Further, the first aspect may further include a light reflection layer that reflects light around the light emitting element. This makes it possible to further improve the light extraction efficiency. In this case, the light reflection layer may have a spread angle in a direction of the condenser lens.

Further, in the first aspect, the condenser lens may include a color change layer. This makes it possible to integrally form the color change layer and the condenser lens.

Further, in the first aspect, the scattering lens may include a color change layer. This makes it possible to integrally form the color change layer and the scattering lens.

Further, the first aspect may further include a counter substrate between the scattering lens and the condenser lens.

Further, in the first aspect, the scattering lens and the condenser lens are provided at positions displaced from a central axis of the light emitting element by a predetermined distance. This makes it possible to change a direction of light from the light emitting element to an arbitrary direction.

Further, a second aspect of the present technology is a method of manufacturing a display device, the method including: a step of forming an electrode on a substrate; a step of forming a light emitting element on the electrode; a step of forming a protective layer that covers the light emitting element; a step of forming a curved shape on the protective layer; a step of forming a condenser lens along the curved shape; and a step of forming a scattering lens on a surface of the condenser lens. With this configuration, it is possible to manufacture a display device in which light is condensed by the condenser lens, and the condensed light is scattered by the scattering lens, thereby improving the light extraction efficiency and the luminance viewing angle characteristic.

### Effects of the Invention

The present technology can have an excellent effect of improving light extraction efficiency and a luminance viewing angle characteristic. Note that the effects described herein are not necessarily limited, and may be any of the effects described in the present disclosure.

### BRIEF DESCRIPTION OF DRAWINGS

FIG. 1 illustrates an example of an overall configuration of a display device 100 according to an embodiment of the present technology.

FIG. 2 illustrates a circuit configuration example of a pixel circuit 101 according to an embodiment of the present technology.

FIG. 3 illustrates an example of a schematic sectional structure of a light emitting module portion of the display device 100 according to an embodiment of the present technology.

FIG. 4 illustrates an example of an optical path according to an embodiment of the present technology.

FIG. 5 illustrates an example of a manufacturing process of a light emitting module portion of the display device 100 according to an embodiment of the present technology.

FIG. 6 illustrates a first modification example of a light emitting module portion according to an embodiment of the present technology.

FIG. 7 illustrates a second modification example of a light emitting module portion according to an embodiment of the present technology.

FIG. 8 illustrates a third modification example of a light emitting module portion according to an embodiment of the present technology.

FIG. 9 illustrates a fourth modification example of a light emitting module portion according to an embodiment of the present technology.

FIG. 10 illustrates a fifth modification example of a light emitting module portion according to an embodiment of the present technology.

FIG. 11 illustrates a sixth modification example of a light emitting module portion according to an embodiment of the present technology.

FIG. 12 illustrates a seventh modification example of a light emitting module portion according to an embodiment of the present technology.

FIG. 13 illustrates an eighth modification example of a light emitting module portion according to an embodiment of the present technology.

FIG. 14 illustrates a ninth modification example of a light emitting module portion according to an embodiment of the present technology.

FIG. 15 illustrates a tenth modification example of a light emitting module portion according to an embodiment of the present technology.

FIG. 16 illustrates an eleventh modification example of a light emitting module portion according to an embodiment of the present technology.

FIG. 17 illustrates a twelfth modification example of a light emitting module portion according to an embodiment of the present technology.

FIG. 18 illustrates a thirteenth modification example of a light emitting module portion according to an embodiment of the present technology.

FIG. 19 illustrates a fourteenth modification example of a light emitting module portion according to an embodiment of the present technology.

FIG. 20 illustrates a fifteenth modification example of a light emitting module portion according to an embodiment of the present technology.

FIG. 21 illustrates appearance of a smartphone 401 that is a first application example of an embodiment of the present technology.

FIG. 22 illustrates appearance of a digital camera 411 that is a second application example of an embodiment of the present technology, as viewed from the front (subject side).

FIG. 23 illustrates appearance of the digital camera 411 that is the second application example of the embodiment of the present technology, as viewed from the rear.

FIG. 24 illustrates appearance of an HMD 431 that is a third application example of an embodiment of the present technology.

### MODE FOR CARRYING OUT THE INVENTION

Hereinafter, a mode for carrying out the present technology (hereinafter, referred to as “embodiment”) will be described. Description will be made in the following order.

1. Embodiment

2. Modification examples

3. Application examples

### 1. Embodiment

### [Configuration of Display Device]

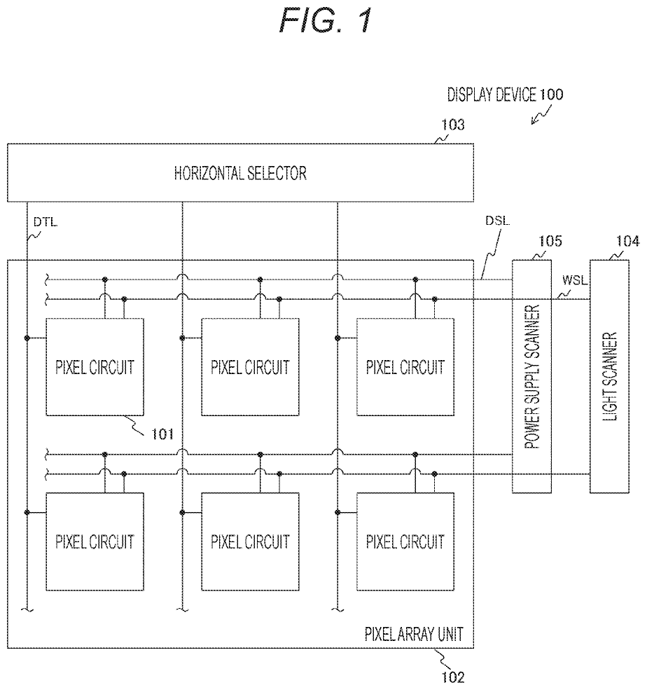

FIG. 1 illustrates an example of an overall configuration of a display device 100 according to an embodiment of the present technology.

The display device 100 includes, for example, a pixel array unit 102 and a drive unit that drives the pixel array unit 102. The drive unit includes a horizontal selector 103, a light scanner 104, and a power supply scanner 105.

The pixel array unit 102 includes a plurality of pixel circuits 101 arranged in a matrix. A power supply line DSL and a scanning line WSL are provided. corresponding to each row of the plurality of pixel circuits 101. Further, a signal line DTL is provided corresponding to each column of the plurality of pixel circuits 101.

The light scanner 104 sequentially supplies a control signal to each of the scanning lines WSL, and line-sequentially scans the pixel circuits 101 in the unit of row. The power supply scanner 105 supplies a power supply voltage to each of the power supply lines DSL in accordance with line-sequential scanning. The horizontal selector 103 supplies a signal potential serving as a video signal and a reference potential to the signal lines DTL in the columns in accordance with the line-sequential scanning.

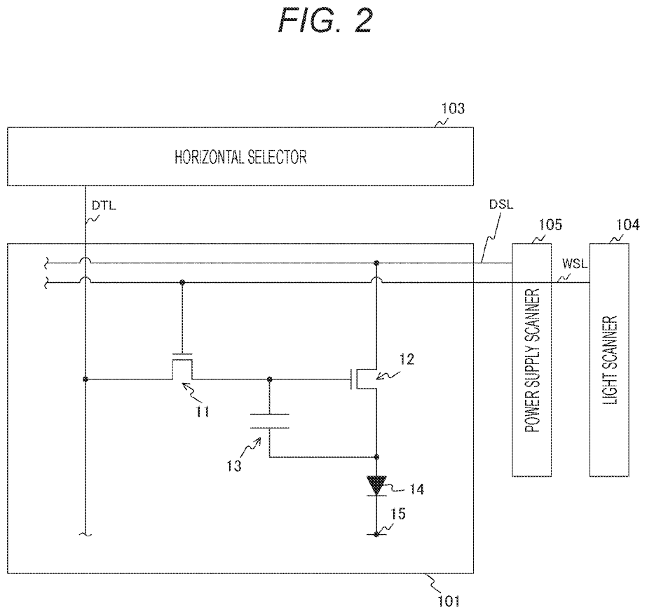

FIG. 2 illustrates a circuit configuration example of the pixel circuit 101 according to the embodiment of the present technology.

The pixel circuit 101 includes, for example, a light emitting element 14 such as an organic EL element, a sampling transistor 11, a driving transistor 12, and a storage capacitor 13.

The sampling transistor 11 has a gate connected to the corresponding scanning line WSL, one of a source and a drain connected to the corresponding signal line DTL, and the other of the source and the drain connected to a gate of the driving transistor 12.

The driving transistor 12 has a source connected to an anode of the light emitting element 14 and a drain connected to the corresponding power supply line DSL. A cathode of the light emitting element 14 is connected to a ground wiring 15. Note that the ground wiring 15 is wired with respect to all the pixel circuits 101 in common.

The storage capacitor 13 is connected between the source and the gate of the driving transistor 12. The storage capacitor 13 holds the signal potential of the video signal supplied from the signal line DTL.

### [Pixel Structure]

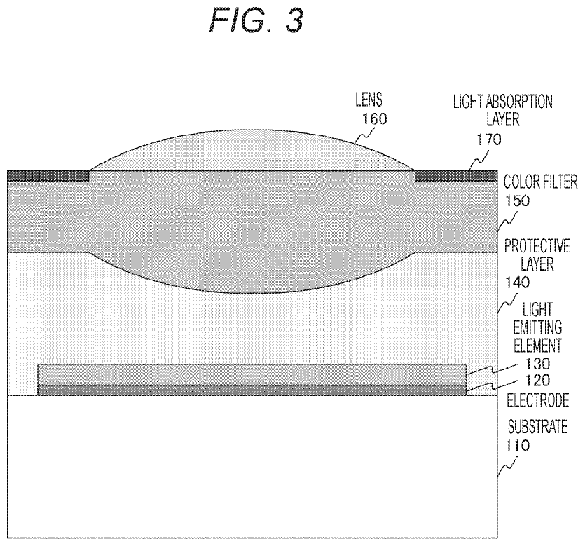

FIG. 3 illustrates an example of a schematic sectional structure of a light emitting module portion of the display device 100 according to the embodiment of the present technology.

A pixel in this embodiment includes an electrode 120, a light emitting element 130, a protective layer 140, a color filter 150, a lens 160, and a light absorption layer 170 on a substrate 110.

The electrode 120 is an anode electrode of the light emitting element 130, and is assumed to be, for example, a transparent electrode made from a metal such as an AlCu alloy or tin (Ti), indium tin oxide (ITC), or the like.

The light emitting element 130 is the above light emitting element 14 that converts an electric signal into an optical signal, and is assumed to be, for example, an organic EL element. In this case, an organic layer is formed between a cathode electrode and the electrode 120. A material of the cathode electrode is assumed to be, for example, a transparent electrode made from an MgAg alloy or indium tin oxide (ITO), or the like.

The protective layer 140 is a barrier layer that covers the light emitting element 130 and prevents deterioration of the light emitting element 130. A material of the protective layer 140 is assumed to be, for example, silicon nitride (SiN).

The color filter 150 is a color change member that changes color of light emitted from the light emitting element 130. The color filter 150 is formed by, for example, mixing an organic pigment with an organic material such as a photoresist and performing photolithography. The color filter 150 has color arrangement such as a Bayer array, for example. Color of the pixel may be white, and, in that case, the color filter 150 is a transparent filter that passes ail colors and does not change the color of light.

In this embodiment, the color filter 150 has a curved shape at a boundary surface with the protective layer 140. Therefore, the color filter 150 functions as a condenser lens that condenses light emitted from the light emitting element.

The lens 160 is an optical element provided on the color filter 150. The lens 160 functions as a scattering lens that scatters the light condensed by the condenser lens of the color filter 150. The color filter 150 and the lens 160 are both made from resin, and can also be made from the same material. However, the lens 160 needs to be made from a transparent material.

The light absorption layer 170 is a layer that is provided around the lens 160 on the color filter 150 and absorbs the light condensed by the condenser lens of the color filter 150.

### [Optical Path]

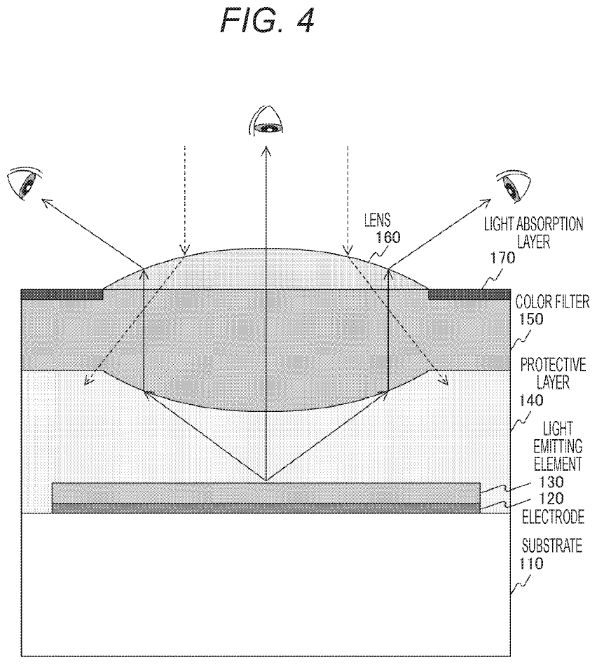

FIG. 4 illustrates an example of an optical path according to the embodiment of the present technology.

Light emitted from the light emitting element in is condensed by the condenser lens of the color filter 150 and is scattered by the scattering lens of the lens 160, as shown by a solid line in FIG. 4. Combination of the condenser lens and the scattering lens improves light extraction efficiency of the light emitted from the light emitting element 130. Further, a luminance viewing angle can be increased by the scattering of light by the scattering lens.

Meanwhile, external light from the front of the lens 160 is scattered by the scattering lens of the lens 160 as shown by a dotted line in FIG. 4, and therefore hardly reaches the light emitting element 130. This makes it possible to reduce reflection of external light on the light emitting element 130.

### [Manufacturing Process]

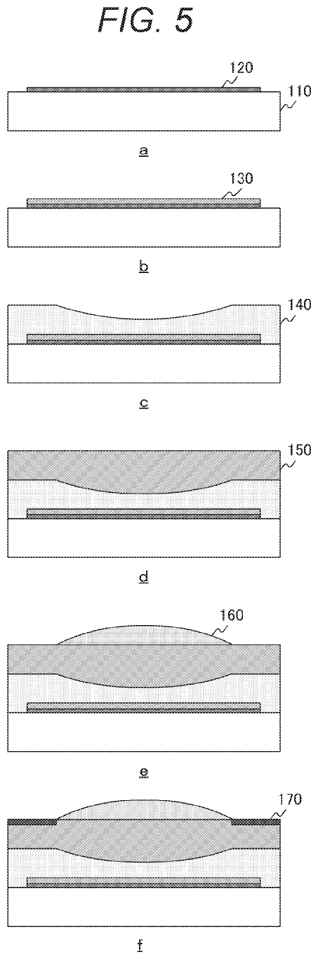

FIG. 5 illustrates an example of a manufacturing process of the light emitting module portion of the display device 100 according to the embodiment of the present technology.

First, as illustrated in a of FIG. 5, the electrode 120 is formed on the substrate 110. The electrode 120 is formed by lithography. Specifically, the electrode 120 is formed by depositing a material from which the electrode 120 is made, patterning the material thereafter, masking the material with a resist to remove an unnecessary portion by etching, and removing the resist used for the masking.

Then, as illustrated in b of FIG. 5, the light emitting element 130 is formed on the electrode 120. The light emitting element 130 is formed by vapor deposition. That is, the light emitting element 130 is formed by depositing, in a vapor phase, a than film of a material from which the light emitting element 130 is made.

Then, as illustrated in c of FIG. 5, the protective layer 140 is formed on a surface of the substrate on which the light emitting element 130 is formed. The protective layer 140 is formed by chemical vapor deposition (CVD). At this time, a curved shape is formed by using a resist on a surface of the protective layer 140.

Then, the color filter 150 is formed as illustrated in d of FIG. 5. The color filter 150 is formed along the curved shape of the surface of the protective layer 140 and functions as a condenser lens. The color filter 150 is formed by lithography or chemical vapor deposition.

Then, the lens 160 is formed as illustrated in e of FIG. 5. The lens 160 functions as a scattering lens. The lens 160 is formed by lithography.

Then, as illustrated in f of FIG. 5, the light absorption layer 170 is formed around the lens 160. The light absorption layer 170 is formed by lithography.

As described above, according to the embodiment of the present technology, combination of the condenser lens and the scattering lens can improve the light extraction efficiency and the luminance viewing angle characteristic and reduce reflection of external light. Reflection of external light is particularly problematic in white pixels, and thus it is particularly useful to apply this embodiment to white pixels.

### 2. Modification Examples

In the above embodiment, the concave condenser lens is integrally formed with a lower surface of the color filter 150, and the lens 160 is separately provided on the color filter 150 as a convex scattering lens. However, the functions of the condenser lens and the scattering lens can be adjusted not only by concave and convex shapes but also by a refractive index of a material. Hereinafter, in addition to the shapes of the lenses, various modification examples for realizing absorption or reflection of light will be described.

### First Modification Example

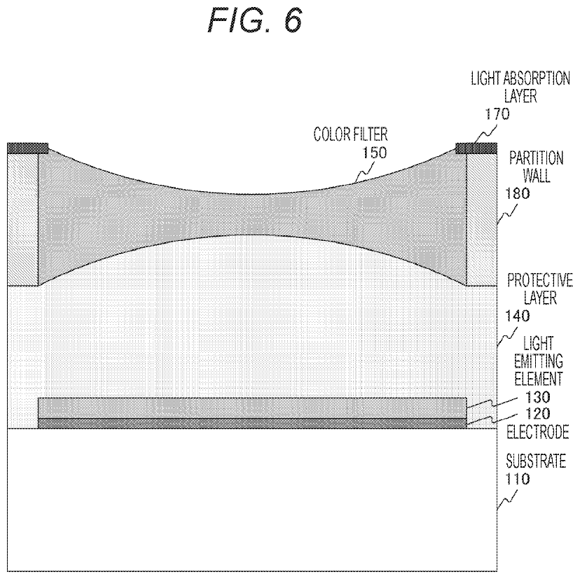

FIG. 6 illustrates a first modification example of the light emitting module portion according to the embodiment of the present technology.

In the first modification example, the lens 160 according to the above embodiment is not separately provided, and a concave scattering lens is integrally formed with an upper surface of the color filter 150 instead. Therefore, the color filter 150 functions as both a condenser lens and a scattering lens, and thus it is possible to omit a step of forming the lens 160.

Further, in the first modification example, a partition wall 180 is provided around the pixel. The partition wall 180 is a wall that is made from a color change member or a light, reflection layer and separates the pixel from other pixels. This makes it possible to prevent color from mixing with colors of other adjacent pixels.

### Second Modification Example

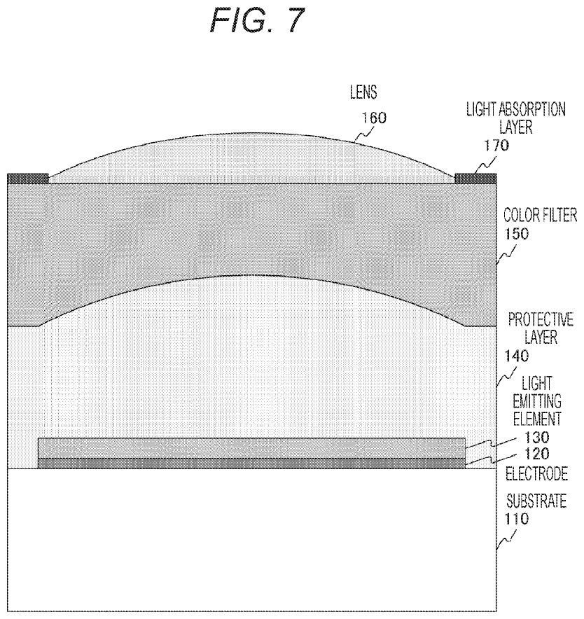

FIG. 7 illustrates a second modification example of the light emitting module portion according to the embodiment of the present technology.

In the second modification example, a convex condenser lens is integrally formed with the lower surface of the color filter 150. That is, a concave or convex shape of the condenser lens is different from that in the above embodiment, and other structures are similar to those in the above embodiment.

### Third Modification Example

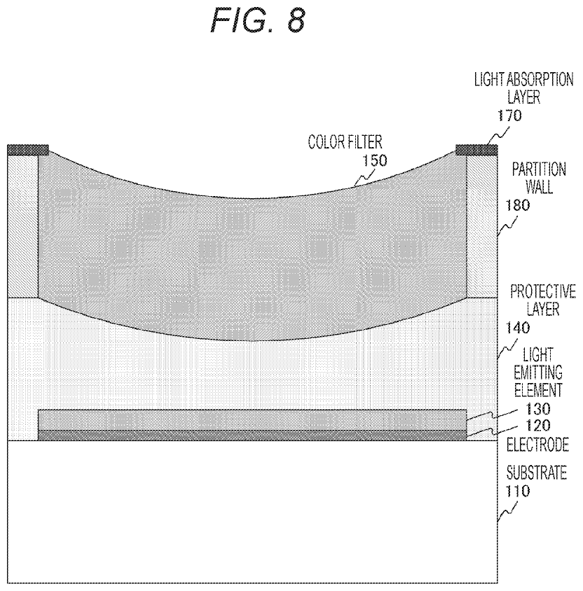

FIG. 8 illustrates a third modification example of the light emitting module portion according to the embodiment of the present technology.

In the third modification example, a concave scattering lens is integrally formed with the upper surface of the color filter 150, and a concave condenser lens is integrally formed with the lower surface of the color filter 150. That is, the concave or convex shape of the condenser lens integrally formed with the lower surface of the color filter 150 is different from that in the above first modification example, and other structures are similar to those in the above first modification example.

### Fourth Modification Example

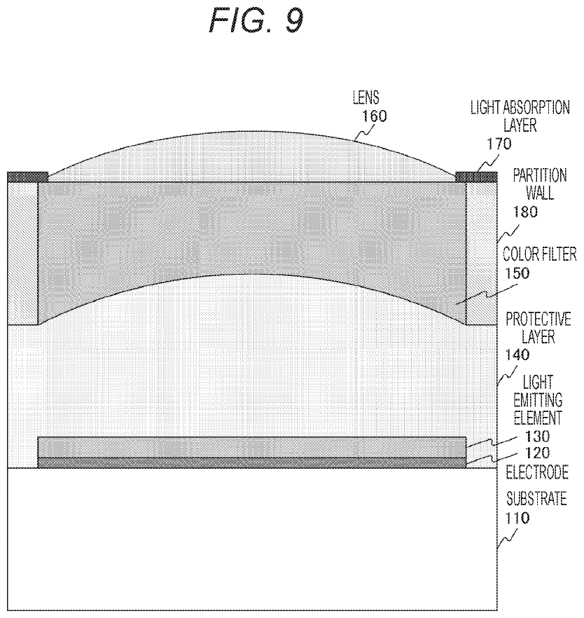

FIG. 9 illustrates a fourth modification example of the light emitting module portion according to the embodiment of the present technology.

In the fourth modification example, a convex condenser lens is integrally formed with the lower surface of the color filter 150, and the partition wall 180 is provided around the pixel. That is, the fourth modification example has a structure in which the partition wall 180 is provided in the above second modification example.

### Fifth Modification Example

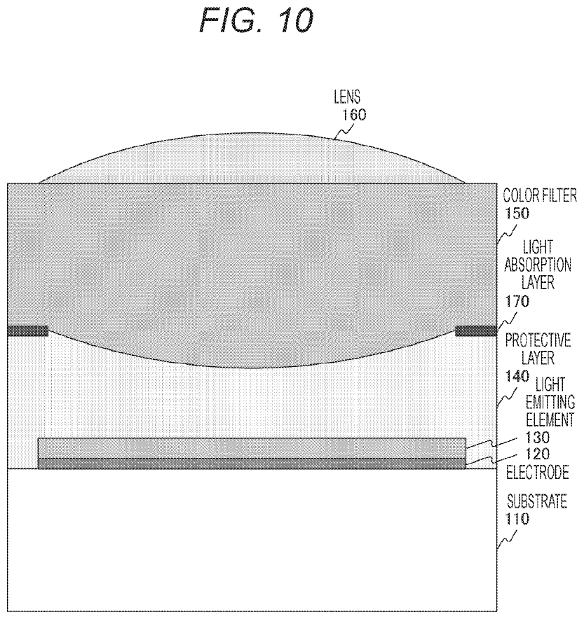

FIG. 10 illustrates a fifth modification example of the light emitting module portion according to the embodiment of the present technology.

In the fifth modification example, the light absorption layer 170 according to the above embodiment is provided not around the lens 160 but around the condenser lens of the color filter 150. That is, the light absorption layer 170 may be provided around either the condenser lens or the scattering lens.

### Sixth Modification Example

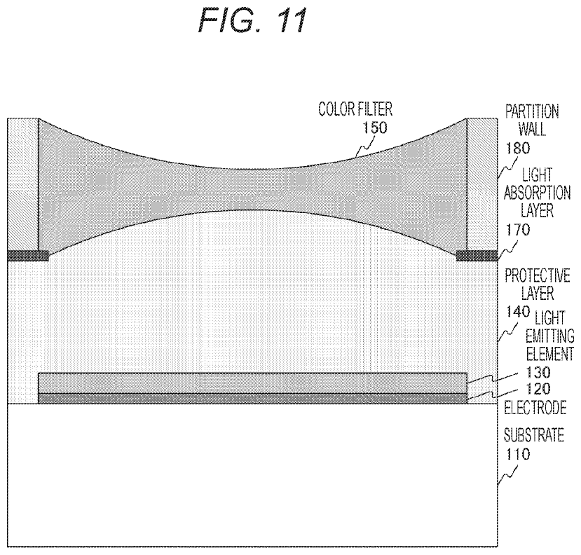

FIG. 11 illustrates a sixth modification example of the light emitting module portion according to the embodiment of the present technology.

In the sixth modification example, the light absorption layer 170 according to the above first modification example is provided not around the lens 160 but around the condenser lens of the color filter 150. Other structures are similar to those in the above first modification example.

### Seventh Modification Example

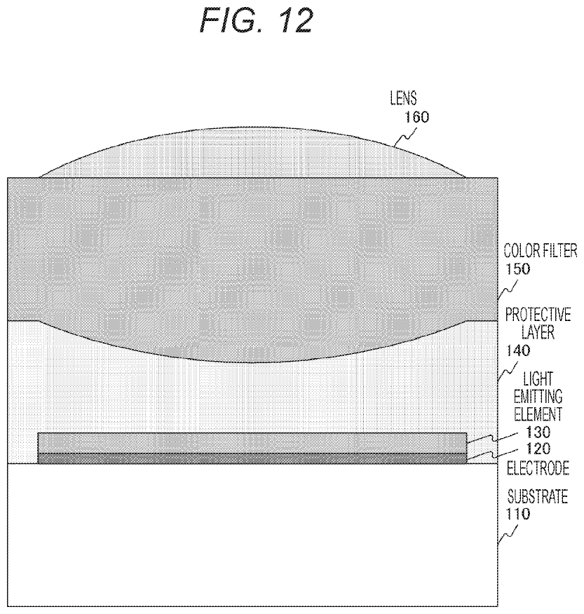

FIG. 12 illustrates a seventh modification example of the light emitting module portion according to the embodiment of the present technology.

In the seventh modification example, the light absorption layer 170 according to the above embodiment is removed. That is, the Light absorption layer 170 is an arbitrary structure for enhancing the effect, and it is possible to obtain the effect of the embodiment of the present technology by providing the condenser lens and the scattering lens in combination.

### Eighth Modification Example

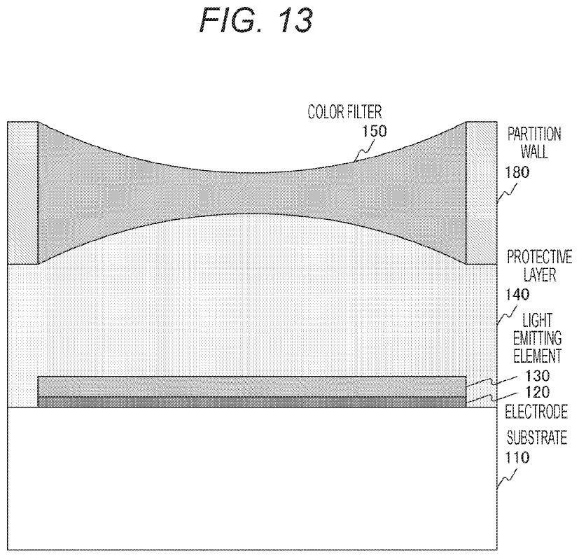

FIG. 13 illustrates an eighth modification example of the light emitting module portion according to the embodiment of the present technology.

In the eighth modification example, the light absorption layer 170 according to the above first or sixth modification example is removed. That is, as described above, the light absorption layer 170 is an arbitrary structure for enhancing the effect, and it is possible to obtain the effect of the embodiment of the present technology by providing the condenser lens and the scattering lens in combination.

### Ninth Modification Example

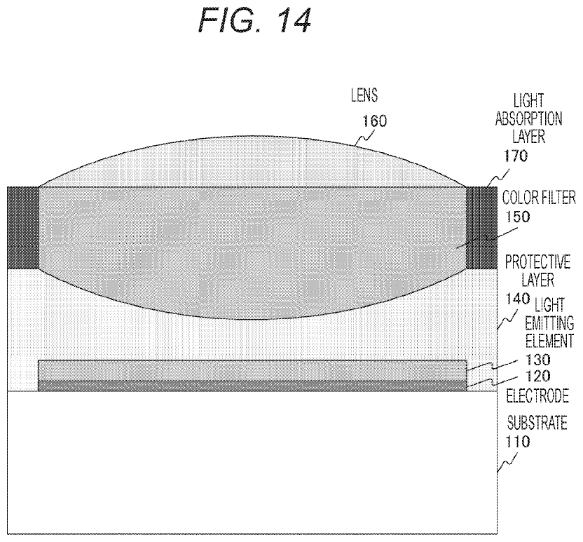

FIG. 14 illustrates a ninth modification example of the light emitting module portion according to the embodiment of the present technology.

In the ninth modification example, the light absorption layer 170 according to the above embodiment is provided as a partition wall. That is, the light absorption layer 170 is provided not as a film-like structure around either the condenser lens or the scattering lens, but as a partition wall that separates the pixel from other pixels in the color filter 150.

This makes it possible to prevent color from mixing with colors of other adjacent pixels.

### Tenth Modification Example

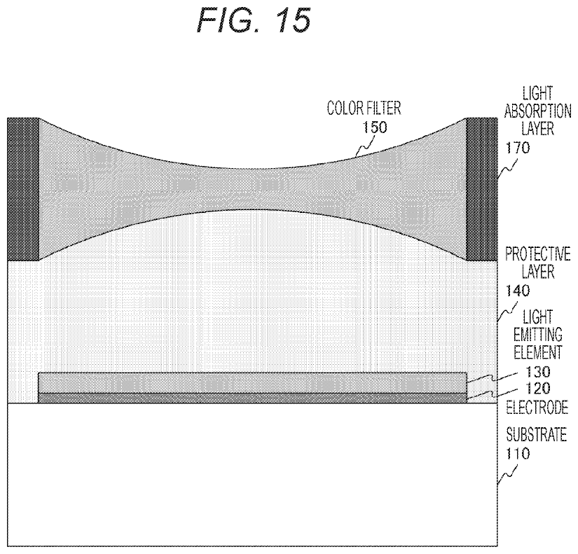

FIG. 15 illustrates a tenth modification example of the light emitting module portion according to the embodiment of the present technology.

In the tenth modification example, the light absorption layer 170 according to the above first or sixth modification example is provided as a partition wall. That is, the light absorption layer 170 is provided not as a film-like structure around either the condenser lens or the scattering lens, but as a partition wall having a light absorbing function instead of the above partition wall 180.

### Eleventh Modification Example

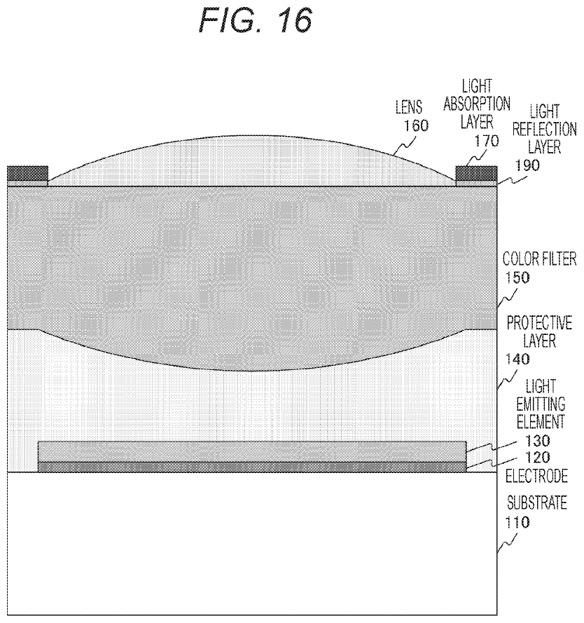

FIG. 16 illustrates an eleventh modification example of the light emitting module portion according to the embodiment of the present technology.

In the eleventh modification example, a light reflection layer 190 is provided under the light absorption layer 170 according to the above embodiment. This makes it possible to reflect light travelling toward a periphery of the pixel within the pixel, thereby further improving the light extraction efficiency.

### Twelfth Modification Example

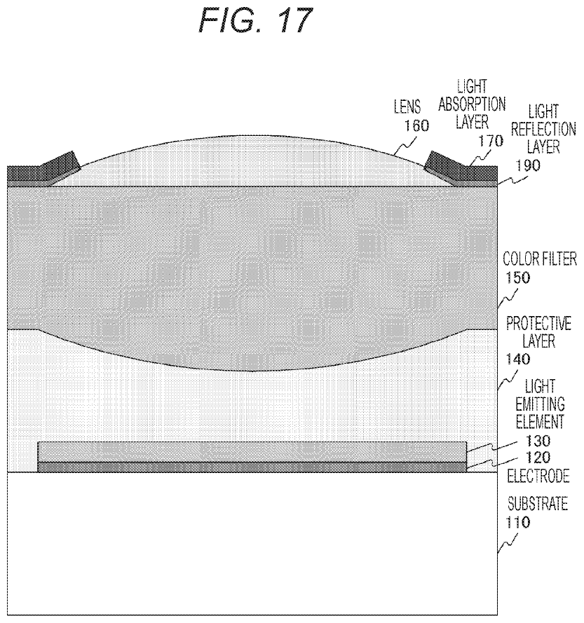

FIG. 17 illustrates a twelfth modification example of the light emitting module portion according to the embodiment of the present technology.

In the twelfth modification example, the light absorption layer 170 and the light reflection layer 190 according to the above eleventh modification example cover part of the lens 160. This makes it possible to further reduce reflection of external light.

### Thirteenth Modification Example

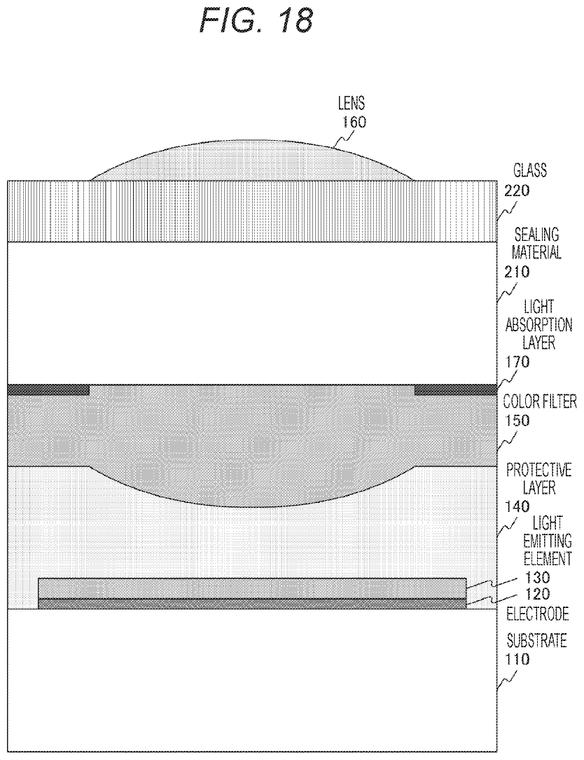

FIG. 18 illustrates a thirteenth modification example of the light emitting module portion according to the embodiment of the present technology.

In the thirteenth modification example, a counter substrate made from glass 220 is provided on the color filter 150 according to the above embodiment with a sealing material 210 interposed therebetween, and the lens 160 is provided thereon. That is, at least part of the condenser lens and the scattering lens may be formed on the counter substrate.

### Fourteenth Modification Example

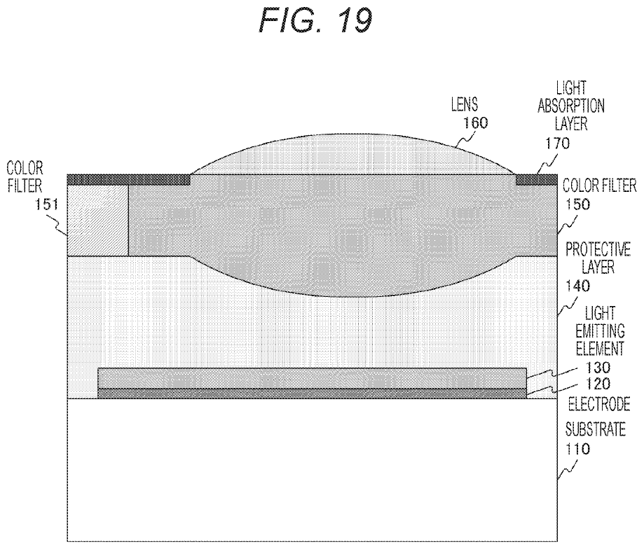

FIG. 19 illustrates a fourteenth modification example of the light emitting module portion according to the embodiment of the present technology.

In the fourteenth modification example, the scattering lens of the lens 160 and the condenser lens of the color filter 150 are provided at positions displaced from a central axis of the light emitting element 130 by a predetermined distance. Therefore, FIG. 19 illustrates a color filter 151 of an adjacent pixel. This makes it possible to change a direction of the light from the light emitting element 130 not to a forward direction (vertical direction) but to an arbitrary direction (right direction in FIG. 19) as necessary.

### Fifteenth Modification Example

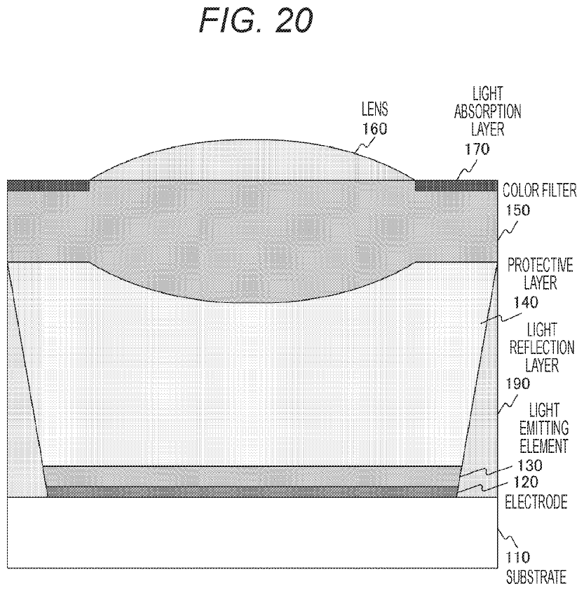

FIG. 20 illustrates a fifteenth modification example of the light emitting module portion according to the embodiment of the present technology.

In the fifteenth modification example, the light reflection layer 190 is provided on a side wall of the light emitting element 130 according to the above embodiment. This makes it possible to reflect light travelling toward a periphery of the pixel within the pixel, thereby further improving the light extraction efficiency. As illustrated in FIG. 20, this structure adopts a reflector structure having a spread angle in a direction of the condenser lens of the color filter 150, thereby improving reflection efficiency.

### 3. Application Examples

Hereinafter, examples of an electronic device to which the display device according to the above embodiment is applicable will be described.

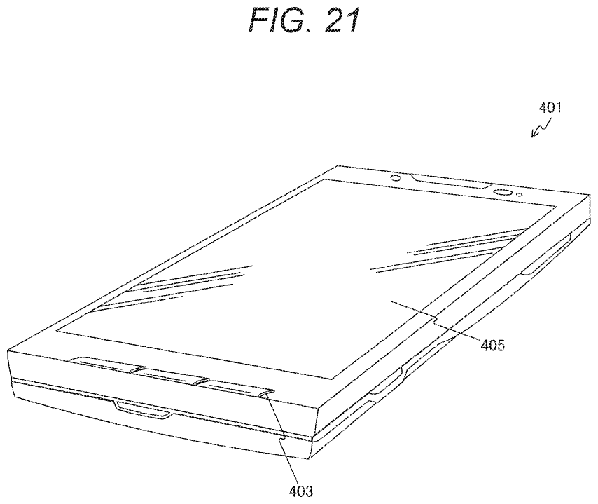

FIG. 21 illustrates appearance of a smartphone 401 that is a first application example of the embodiment of the present technology. The smartphone 401 includes an operation unit 403 that accepts an operation input from a user and a display unit 405 that displays various kinds of information. The display unit 405 can be configured by the display device according to the above embodiment.

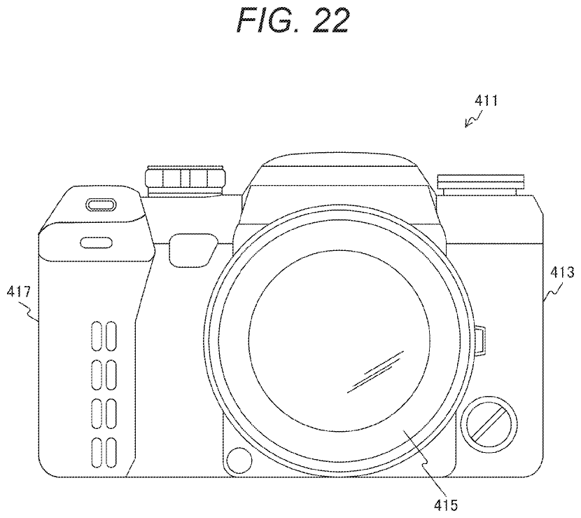

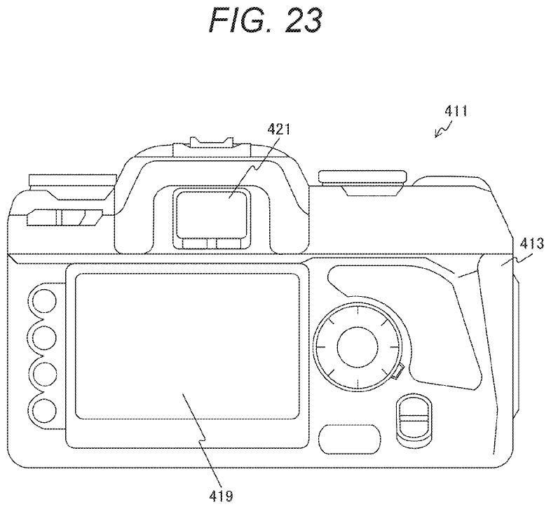

FIG. 22 illustrates appearance of a digital camera 411 that is a second application example of the embodiment of the present technology, as viewed from the front (subject side). FIG. 23 illustrates appearance of the digital camera 411 that is the second application example of the embodiment of the present technology, as viewed from the rear. The digital camera 411 includes a main body portion (camera body) 413, an interchangeable lens unit 415, and a grip portion 417 gripped by the user during imaging. Further, the digital camera 411 includes a monitor 419 that displays various kinds of information and an electronic viewfinder (EVF) 421 that displays a through image observed by the user during imaging. The monitor 419 and the EVF 421 can be configured by the display device according to the above embodiment.

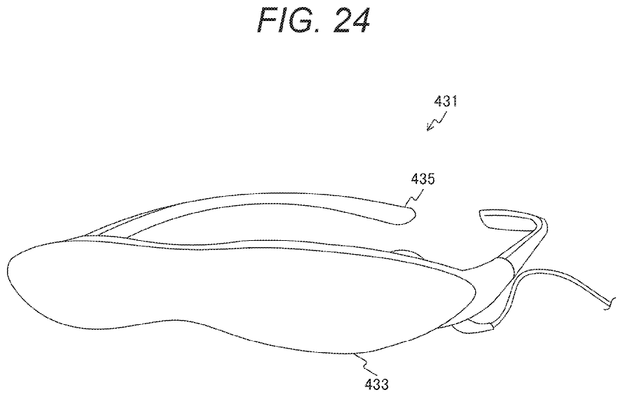

FIG. 24 illustrates appearance of an HMD 431 that is a third application example of the embodiment of the present technology. The head mounted display (HMD) 431 includes a spectacle-type display unit 433 that displays various kinds of information and ear hook portions 435 hooked on ears of the user when worn. The display unit 433 can be configured by the display device according to the above embodiment.

Hereinabove, several examples of the electronic device to which the display device according to each embodiment is applicable have been described. Note that electronic devices to which the display device according to each embodiment is applicable are not limited to those exemplified above. The display device is applicable to a display device mounted on an electronic device in any field which performs display on the basis of an image signal input from the outside or an image signal generated thereinside, such as a television device, an electronic book, a PDA, a laptop computer, a video camera, or a game console.

Note that the above embodiments show examples for embodying the present technology, and the matters in the embodiments and the matters specifying the invention in the claims have a corresponding relationship. Similarly, the matters specifying the invention in the claims and the matters in the embodiments of the present technology represented by the same names as those in the matters specifying the invention in the claims have a corresponding relationship. However, the present technology is not limited to the embodiments, and can be embodied by applying various modification examples to the embodiments within the gist thereof.

Note that the effects described in this specification are merely examples, are not limited, and may have other effects.

Note that the present technology may also have the following configurations.

(1) A display device including:
a light emitting element;
a condenser lens that condenses light emitted from the light emitting element; and
a scattering lens that scatters the light condensed by the condenser lens.

(2) The display device according to (1), in which:
a plurality of pixels is arranged on a plane; and
at least one of the plurality of pixels includes a set of the light emitting element, the condenser lens, and the scattering lens.

(3) The display device according to (2), further including
a partition wall around the pixel.

(4) The display device according to (3), in which
the partition wall reflects light in the pixel.

(5) The display device according to (3), in which
the partition wall absorbs light in the pixel.

(6) The display device according to any one of (2) to (5), in which
the set of the light emitting element, the condenser lens, and the scattering lens is provided only in a pixel of a specific color.

(7) The display device according to (6), in which
the pixel of the specific color is a white pixel.

(8) The display device according to any one of (1) to (7), further including
a light absorption layer that absorbs light around the condenser lens or the scattering lens.

(9) The display device according to (8), in which
the light absorption layer covers part of the condenser lens or the scattering lens.

(10) The display device according to (8) or (9), further including
a light reflection layer that reflects light and is provided under the light absorption layer.

(11) The display device according to any one of (1) to (10), further including
a light reflection layer that reflects light around the light emitting element.

(12) The display device according to (11), in which
the light reflection layer has a spread angle in a direction of the condenser lens.

(13) The display device according to any one of (1) to (12), in which
the condenser lens includes a color change layer.

(14) The display device according to any one of (1) to (13), in which
the scattering lens includes a color change layer.

(15) The display device according to any one of (1) to (14), further including
a counter substrate between the scattering lens and the condenser lens.

(16) The display device according to any one of (1) to (15), in which
the scattering lens and the condenser lens are provided at positions displaced from a central axis of the light emitting element by a predetermined distance.

(17) A method of manufacturing a display device, the method including:
a step of forming an electrode on a substrate;
a step of forming a light emitting element on the electrode;
a step of forming a protective layer that covers the light emitting element;
a step of forming a curved shape on the protective layer;
a step of forming a condenser lens along the curved shape; and
a step of forming a scattering lens on a surface of the condenser lens.

### REFERENCE SIGNS LIST

11 Sampling transistor

12 Driving transistor

13 Storage capacitor

14 Light emitting element

15 Ground wiring

100 Display device

101 Pixel circuit

102 Pixel array unit

103 Horizontal selector

104 Light scanner

105 Power supply scanner

110 Substrate

120 Electrode

130 Light emitting element

140 protective layer

150, 151 Color filter

160 Lens

170 Light absorption layer

180 Partition wall

190 Light reflection layer

210 Sealing material

220 Glass

1. A display device comprising:
a light emitting element;
a condenser lens that condenses light emitted from the light emitting element; and
a scattering lens that scatters the light condensed by the condenser lens.

2. The display device according to claim 1, wherein:
a plurality of pixels is arranged on a plane; and
at least one of the plurality of pixels includes a set of the light emitting element, the condenser lens, and the scattering lens.

3. The display device according to claim 2, further comprising
a partition wall around the pixel.

4. The display device according to claim 3, wherein
the partition wall reflects light in the pixel.

5. The display device according to claim 3, wherein
the partition wall absorbs light in the pixel.

6. The display device according to claim 2, wherein
the set of the light emitting element, the condenser lens, and the scattering lens is provided only in a pixel of a specific color.

7. The display device according to claim 6, wherein
the pixel of the specific color is a white pixel.

8. The display device according to claim 1, further comprising
a light absorption layer that absorbs light around the condenser lens or the scattering lens.

9. The display device according to claim 8, wherein
the light absorption layer covers part of the condenser lens or the scattering lens.

10. The display device according to claim 8, further comprising
a light reflection layer that reflects light and is provided under the light absorption layer.

11. The display device according to claim 1, further comprising
a light reflection layer that reflects light around the light emitting element.

12. The display device according to claim 11, wherein
the light reflection layer has a spread angle in a direction of the condenser lens.

13. The display device according to claim 1, wherein
the condenser lens includes a color change layer.

14. The display device according to claim 1, wherein
the scattering lens includes a color change layer.

15. The display device according to claim 1, further comprising
a counter substrate between the scattering lens and the condenser lens.

16. The display device according to claim 1, wherein
the scattering lens and the condenser lens are provided at positions displaced from a central axis of the light emitting clement by a predetermined distance.

17. A method of manufacturing a display device, the method comprising:
a step of forming an electrode on a substrate;
a step of forming a light emitting element on the electrode;
a step of forming a protective layer that covers the light emitting element;
a step of forming a curved shape on the protective layer;
a step of forming a condenser lens along the curved shape; and
a step of forming a scattering lens on a surface of the condenser lens.
